(19) United States
(12) Patent Application Publication
(10) Pub. No.: US 2026/0254433 A1
(43) Pub. Date: Aug. 27, 2026

(54) BALUN AND MIXER

(71) Applicant: NANJING MILEWEI CORP, Jiangsu (CN)

(72) Inventors: Xiang CHEN, Jiangsu (CN); Rui LIN, Jiangsu (CN); Yuanji DAI, Jiangsu (CN); Xin JIANG, Jiangsu (CN)

(73) Assignee: NANJING MILEWEI CORP, Jiangsu (CN)

(21) Appl. No.: 18/730,313

(22) PCT Filed: Nov. 22, 2023
(86) PCT No.: PCT/CN2023/133120

§ 371 Date: Jul. 19, 2024

(30) Foreign Application Priority Data
May 18, 2023 (CN) 202310565743.2

(51) Int. Cl. H03H 7/42; H03D 7/16

(52) U.S. Cl. CPC H03H 7/425; H03D 7/161

(57) ABSTRACT

A balun and a mixer are provided. The balun includes a first coil and a second coil that are coupled to each other. An intermediate point of the first coil forms a first input terminal of the balun, and an intermediate point of the second coil forms a second input terminal of the balun. Both terminals of the first coil form a first output terminal and a second output terminal, respectively, and both terminals of the second coil respectively forms a third output terminal and a fourth output terminal, respectively. The third output terminal and the fourth output terminal are the coupling terminals of the first output terminal and the second output terminal, respectively. The first output terminal and the fourth output terminal form a first set of differential output terminals, and the second output terminal and the third output terminal form a second set of differential output terminals.

### TECHNICAL FIELD

The present disclosure relates to the technical field of the circuit design, in particular to a balun and a mixer including the balun.

### DESCRIPTION OF RELATED ART

With the rapid development of the wireless communication technology, the index performance of the mixer directly affects the overall performance of the entire transceiver system. As one of the important components of the transceiver, the requirements for the performance of the mixer are becoming more and more stringent.

The mixer is a tri-port device that relies on the nonlinearity of the circuit itself to complete the frequency conversion function. Generally, these three ports are defined as the input port, the output port and the local oscillator port respectively. When the input frequency is greater than the output frequency, the mixer is an up-conversion mixer, and when the input frequency is less than the output frequency, the mixer is a down-converting mixer.

Since the three ports of the mixer are all required to be input with the differential signals, the passive baluns are required to be adopted at the local oscillator port and the input port to convert the single-ended signals into the differential signals. The isolation, the stability and the uniformity between the input signal and the output signal of the passive balun all affect the performance of the mixer and even the transceiver.

The most commonly used balun structure in the mixer is the Marchand balun structure. FIG. 1 illustrates a Marchand balun structure in the prior art. As illustrated in FIG. 1, the Marchand balun structure includes a first coil W1 and a second coil W2, the first coil W1 and the second coil W2 refer to two sets of coils that respectively form a signal path. The two terminals of each of the two sets of coils are respectively formed two ports, a total of four ports, such as port P1, port P2, port P3 and port P4 as illustrated in FIG. 1. The port P1 and the port P2 are two ports directly connected to each other, and the port P3 and the port P4 are two ports directly connected to each other. When the four ports are connected to the mixer circuit, one of the four ports is served as a signal input terminal, the other port to which the signal input terminal is directly connected is grounded, and the remaining two ports form the differential output terminals.

In the practical application process, in the Marchand balun structure as illustrated in FIG. 1, the amplitude difference and phase difference of the differential output terminals fluctuate greatly with the various of the load impedance, which affects the balance of the amplitude and the phase of the balun characteristics. In the application of the double-balanced passive mixer, the balance between the amplitude and the phase of the local oscillator differential output terminal affects the isolation between the local oscillator signal and the radio frequency signal as well as the local oscillator signal and the intermediate frequency signal of the mixer.

When the input power of the mixer increases, the impedance at the port of the frequency mixing core will be varied due to the injection of the high power, which causes the impedance of the differential output terminal of the balun to change, thereby affecting the loss of the balun itself and the consistency of the amplitude and the phase of the differential output terminal, and eventually affecting the output power of the differential output terminal.

In summary, the characteristics of the balun affect the linearity and the isolation of the mixer, and affect the mixing effect.

In order to solve the above-mentioned problems, a balun and a mixer using the balun is proposed by the present disclosure.

### SUMMARY

A brief overview of one or more aspects is given below to provide a basic understanding of these aspects. The overview is not an exhaustive overview of all envisaged aspects and is neither intended to identify the key or decisive elements in all aspects nor an attempt to define the scope of any or all aspects. The sole purpose is to give some concepts of one or more aspects in simplified form as a prelude to a more detailed description given later.

Provided according to one aspect of the present disclosure is a balun.

In one embodiment, a balun comprises a fist coil and a second coil coupled to each other, an intermediate point of the first coil forms a first input terminal of the balun, an intermediate point of the second coil forms a second input terminal of the balun, both terminals of the first coil forms a first output terminal and a second output terminal of the balun, respectively, both terminals of the second coil form a third output terminal and a fourth output terminal of the balun, respectively, the third output terminal and the fourth output terminal are coupling terminals of the first output terminal and the second output terminal, respectively, and the first output terminal and the fourth output terminal form a first set of differential output terminals, and the second output terminal and the third output terminal form a second set of differential output terminals.

In one embodiment, one of the first input terminal and the second input terminal is configured to connect an input signal, another one of the first input terminal and the second input terminal is grounded, one of the first set of differential output terminals and the second set of differential output terminals is configured to output a differential signal, and the other one of the first set of differential output terminals and the second set of differential output terminals is grounded.

In one embodiment, the first coil is divided into a first inductor and a second inductor that are in equal to each other by the intermediate point of the first coil, the second coil is divided into a third inductor and a fourth inductor that are in equal to each other by the intermediate point of the second coil, the first inductor is coupled to the third inductor, and the second inductor is coupled to the fourth inductor.

In one embodiment, the first coil is divided into a first inductor and a second inductor that are in equal to each other by the intermediate point of the first coil, the second coil is divided into a third inductor and a fourth inductor that are in equal to each other by the intermediate point of the second coil, the first inductor is coupled to the third inductor and the fourth inductor, respectively, and the second inductor is coupled to the third inductor and the fourth inductor, respectively, to form a cross-coupled structure.

According to another aspect of the present disclosure, a mixer is further provided by the present disclosure. The mixer comprises a local oscillator balun, a frequency mixing core and a radio frequency balun. An input terminal of the local oscillator balun is in connection with a local oscillator signal, a differential output terminal of the local oscillator balun is in connection with a local oscillator input terminal of the frequency mixing core, an input terminal of the radio frequency balun is in connection with an input signal, and a differential output terminal of the radio frequency balun is in connection with a radio frequency input terminal of the frequency mixing core, and the balun according to an arbitrary one of the above-mentioned embodiments is adopted by the local oscillator balun and/or the radio frequency balun.

In one embodiment, the frequency mixing core includes four frequency mixing branches connected from a starting terminal to a rear terminal, each frequency mixing branch includes a plurality of diodes in series, the four frequency mixing branches are sequentially connected with each other from a starting terminal to a rear terminal, connection points of the four frequency mixing branches form a first frequency mixing point, a second frequency mixing point, a third frequency mixing point and a fourth frequency mixing point, respectively, the first frequency mixing point and the third frequency mixing point form a local oscillation signal input terminal of the frequency mixing core, and the second frequency mixing point and the fourth frequency mixing point form an input signal terminal of the frequency mixing core.

In one embodiment, each of the frequency mixing branches includes four diodes in series.

In one embodiment, the balun according to an arbitrarily one of the above-mentioned embodiments is adopted by the local oscillator balun.

In one embodiment, the mixer is a single-ended mixer, the frequency mixing core includes a first switch transistor and a second switch transistor, a gate of the first switch transistor and a gate of the second switch transistor form the local oscillator input terminal, a source of the first switch transistor and a source of the second switch transistor form the radio frequency input terminal, and a drain of the first switching transistor is in connection with a drain of the second switch transistor to form a mixing output terminal of the mixer.

In one embodiment, the mixer is a dual-balanced mixer, the frequency mixer core includes a third switch transistor and a fourth switch transistor symmetrically arranged with each other, as well as a fifth switch transistor and a sixth switch transistor symmetrically arranged with each other, a gate of the third switch transistor and a gate of the fifth switch transistor form one set of local oscillator input terminals, a gate of the fourth switch transistor and a gate of the sixth switch transistor form another set of local oscillator input terminals, a source of the third switch transistor is in connection with a source of the fourth switch to form a positive input terminal, a source of the fifth switch transistor is in connection with a source of the sixth switch transistor to form a negative input terminal, the positive input terminal and the negative input terminal form the radio frequency input terminal, a drain of the third switch transistor is in connection with a drain of the fourth switch transistor to form a positive output terminal of the mixer, a drain of the fifth switch transistor is in connection with a drain of the sixth switch transistor to form a negative output terminal of the mixer, and the positive output terminal and the positive output terminal form a differential output terminal of the mixer.

The present disclosure can improve the consistency of the amplitude and the phase through inputting the single from the intermediate point of the coil of the balun, and outputting the differential signals from the two opposite terminals of the two coils. The linearity and the isolation of the mixer can be improved through incorporating the balun with the above mentioned structure into the mixer, and the isolation can be further improved through setting the capacitor or the inductor in the local oscillator balun and the radio frequency balun, thereby implementing the adjustment of the matching impedance and the balance, and the peak frequency of the third-order intermodulation signal is adjusted through setting the capacitor between the inductor of the radio frequency balun and the fourth frequency mixing point, which can further improve the matching impedance and the balance.

### BRIEF DESCRIPTION OF THE DRAWINGS

The above features and advantages of the present disclosure can be better understood after reading the detailed descriptions of the embodiments of the present disclosure with reference to the following drawings.

FIG. 1 illustrates a schematic diagram of a circuit structure of a balun according to the prior art.

FIG. 2 illustrates a schematic diagram of a circuit structure of a balun in one embodiment according to one aspect of the present disclosure.

FIG. 3 illustrates a schematic diagram of a connection mode of a balun in one embodiment according to one aspect of the present disclosure.

FIG. 4 illustrates a schematic diagram of a coupling relation of a balun in one embodiment according to one aspect of the present disclosure.

FIG. 5 illustrates a schematic diagram of a coupling relation of a balun in one embodiment according to one aspect of the present disclosure.

FIG. 6 illustrates a block diagram of a mixer in one embodiment according to another aspect of the present disclosure.

FIG. 7 illustrates a schematic diagram of a circuit structure of a frequency mixing core of a single-balanced mixer in one embodiment according to another aspect of the present disclosure.

FIG. 8 illustrates a schematic diagram of a circuit structure of a frequency mixing core of a double-balanced mixer in one embodiment according to another aspect of the present disclosure.

FIG. 9 illustrates a schematic diagram of a circuit structure of a frequency mixing core of a diode mixer in one embodiment according to another aspect of the present disclosure.

FIG. 10 illustrates a schematic diagram of a circuit structure of a mixer in an embodiment according to another aspect of the present disclosure.

FIG. 11 illustrates a schematic diagram of a circuit structure of a mixer in an embodiment according to another aspect of the present disclosure.

FIG. 12 illustrates a schematic diagram of a circuit structure of a mixer in an embodiment according to another aspect of the present disclosure.

FIG. 13 illustrates a schematic diagram of a circuit structure of a mixer in an embodiment according to another aspect of the present disclosure.

### DESCRIPTION OF THE EMBODIMENTS

The following descriptions are given to enable those skilled in the art to implement and use the present disclosure and integrate the present disclosure into specific application scenarios. The variations and the various uses in different applications will be obvious to those skilled in the art, and the general principles defined herein may be applicable to a wider range of embodiments. Thus, the present disclosure is not limited to the embodiments given herein, but shall be granted the broadest scope consistent with the principles and novelty characteristics disclosed in the present disclosure.

In the following detailed descriptions, various specific details are described to provide a more thorough understanding on the present disclosure. However, it is obvious to those skilled in the art that the implements of the present disclosure should not be limited to these specific details. In other words, the publicly known structures and devices are shown in block diagram form without being shown in detail to avoid obscuring the present disclosure.

Unless directly stated otherwise, all features revealed in this specification (including all of the attached claims, summaries and drawings) may be replaced by alternative features used to achieve the same, equivalent or similar purposes. Therefore, unless expressly stated otherwise, each feature disclosed is only an example of one set of equivalent or similar features.

Note that, where used, the symbols left, right, front, back, top, bottom, forward, backward, clockwise, and counterclockwise are used for convenient purposes only and do not imply any specific fixed direction. In fact, they are used to reflect the relative position and/or orientation between the various parts of an object. In addition, the terms “first” and “second” are used for describing purposes only and are not understood to indicate or imply relative importance.

In the description of the present disclosure, it should be illustrated that, unless otherwise expressly specified and limited, the terms “connected with”, “connected to”, “cross-connection” shall be understood broadly, for example, it can be directly connected, or indirectly connected through an intermediary, or connected within two components. For those skilled in the art, the specific meanings of the above terms in the present disclosure can be understood according to the specific circumstances.

Note that in the case of use, further, preferably, further, and better optimized are simple starting points for the elaboration of another embodiment on the basis of the preceding embodiment, and the combination of the contents of the further, better, further, or better embodiment with the preceding embodiment constitutes the complete composition of the other embodiment. An embodiment which may be arbitrarily combined between a number of further, better, further or better settings following the same embodiment.

The present disclosure will be described in detail below with reference to the accompanying drawings and specific embodiments. Note that the aspects described below in conjunction with the drawings and specific embodiments are illustrative only and should not be construed as limiting the protection scope of the present disclosure in any way.

According to one aspect of the present disclosure, a balun is provided. Balun is a transformation structure that converts the single-ended transmission into the differential transmission. Balun is also called as a Balance-Unbalance converter (Balance-Unbalance, abbreviated as Balun in English, and transliterated as Balun), which can be used for the push-pull amplifiers, the broadband antennas, the balanced mixers, the balanced frequency multipliers, the modulators, and the phase shifters, as well as one circuit design that requires equal transmission amplitude and 180 degree phase difference between two lines. For the balun, the consistency of the amplitude and the phase of the two ports at the differential output terminal of the balun is an extremely important indicator, which is commonly called the balun characteristic.

FIG. 2 illustrates a schematic diagram of a circuit of a balun in one embodiment. As illustrated in FIG. 2, in this embodiment, the balun includes the coil W3 and the coil W4 that are coupled to each other, which can be regarded as including six ports. Both terminals and the intermediate point of the coil W3 form three ports, and both terminals and the intermediate point of the coil W4 form the other three ports. The intermediate point refers to the point where a coil is divided into two inductors with the same inductance. That is, the coil W3 can be regarded as two inductors L1 and L2 with equal inductance in series, and the coil W4 can be regarded as two inductors L3 and L4 with equal inductance in series, and the inductors L1, L2, L3 and L4 have equal inductance. Then, both terminals of the coil W3 form two output ports Vₒᵤₜ₁ and Vₒᵤₜ₂, and the intermediate point of the coil W3 forms the input port Vᵢₙ₁, and both terminals of the coil W4 form two output ports Vₒᵤₜ₃ and Vₒᵤₜ₄, and the intermediate point of the coil W4 forms the input port Vᵢₙ₂. The output port Vₒᵤₜ₁ and the output port Vₒᵤₜ₃ are one set of adjacent ports of the coil W3 and the coil W4, and the output port Vₒᵤₜ₂ and the output port Vₒᵤₜ₄ are one set of adjacent ports of the coil W3 and the coil W4. In the process of the port definition, one port of one set of adjacent ports and one port on another coil of the other set of adjacent ports are set as one set of differential output terminals, that is, the output port Vₒᵤₜ₁ and the output port Vₒᵤₜ₄ are one set of two sets of differential output terminals, and the output port Vₒᵤₜ₂ and the output port Vₒᵤₜ₃ are the other set of two sets of differential output terminals.

Preferably, the coil W3 and the coil W4 are microstrip lines.

In a specific application, one of the input port Vᵢₙ₁ and the input port Vᵢₙ₂ is in connection with the input signal as a single-ended signal input port, and the other of the input port Vᵢₙ₁ and the input port Vᵢₙ₂ is grounded. One set of the two sets of differential output terminals is configured to output a differential signal as a differential signal output port, the other set of the two sets of differential output terminals is grounded.

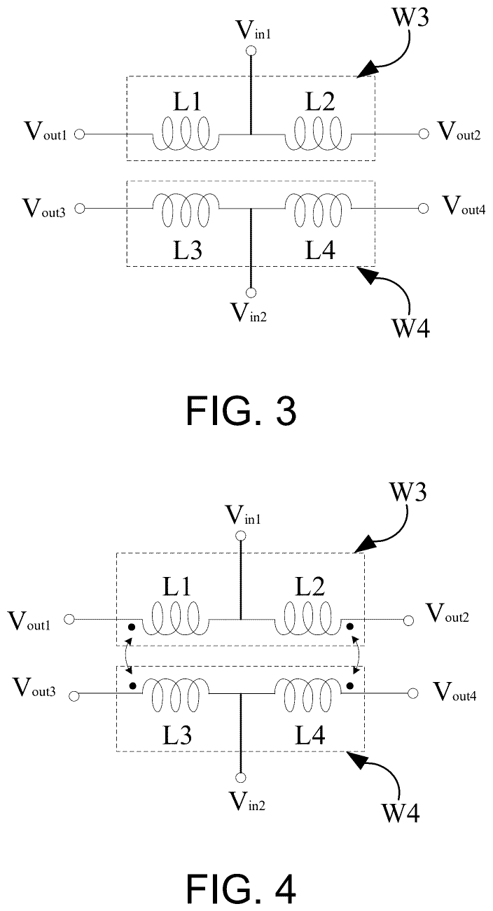

FIG. 3 illustrates a schematic diagram of a circuit connection of a balun in one specific embodiment. As illustrated in FIG. 3, the input port Vᵢₙ₁ is in connection with the input signal, the input port Vᵢₙ₂ is grounded, the output port Vₒᵤₜ₁ and the output port Vₒᵤₜ₄ are configured to output the differential signals, and the output Port Vₒᵤₜ₂ and the output port Vₒᵤₜ₃ are grounded.

The balun as illustrated in FIG. 3 is analyzed by utilizing the odd-even mode equivalent analysis method. The input port Vᵢₙ₁ and the input port Vᵢₙ₂ are served as the differential input terminals, and the output port Vₒᵤₜ₁ and the output port Vₒᵤₜ₄ are served as the differential output terminals. It can be obtained that the output port Vₒᵤₜ₁ and the output port Vₒᵤₜ₄ have the same amplitude and the opposite phase, after the odd and even mode signals are superimposed, which exhibits the balun characteristics and has nothing to do with the load impedance at the differential output terminals. Therefore, the balun characteristics of the output signal of the balun can be guaranteed. The loss of the balun depends on the resistance loss and the coupling degree of the coil itself, so that the balun characteristic can be satisfied in a wide frequency band.

It can be understood that the grounding methods of each port can be directly grounded or indirectly grounded through a capacitor, a resistor or an inductor. However, when the above mentioned components are utilized in the embodiments, the driving performance and the operation frequency band of the output signal of the structure may be affected, which is applicable to some narrowband application scenarios.

Furthermore, under the requirements of the balun characteristics, the methods for implement the coupling relation in the balun circuit can be various.

FIG. 4 illustrates a schematic diagram of the coupling relation of the balun illustrated in FIG. 2 in one embodiment. AS illustrated in FIG. 4, the inductor L1 is coupled to the inductor L3, and the inductor L2 is coupled to the inductor L4.

In the balun structure illustrated in FIG. 4, the inductor L1 and the inductor L2 can be the different line segments in the same inductor coil, and the inductor coil forms the coil W3. Correspondingly, the inductor L3 and the inductor L4 can be the different line segments in the same inductor coil, and the inductor coil forms the coil W4. That is, the coil W3 and the coil W4 form one set of coupling relations. In this implementation, the intermediate points of the coil W3 and the coil W4 refer to the physical intermediate points corresponding to the winding inductors.

In the balun structure illustrated in FIG. 4, the inductor L1 and the inductor L2 can also be two inductor coils, and the two inductor coils form the coil W3. Correspondingly, the inductor L3 and the inductor L4 can also be two inductor coils, and the two inductor coils form the coil W4. That is, the coil W3 and the coil W4 form two sets of coupling relations. In this implementation, the intermediate points of the coil W3 and the coil W4 refer to the connection points corresponding to the two inductors in series.

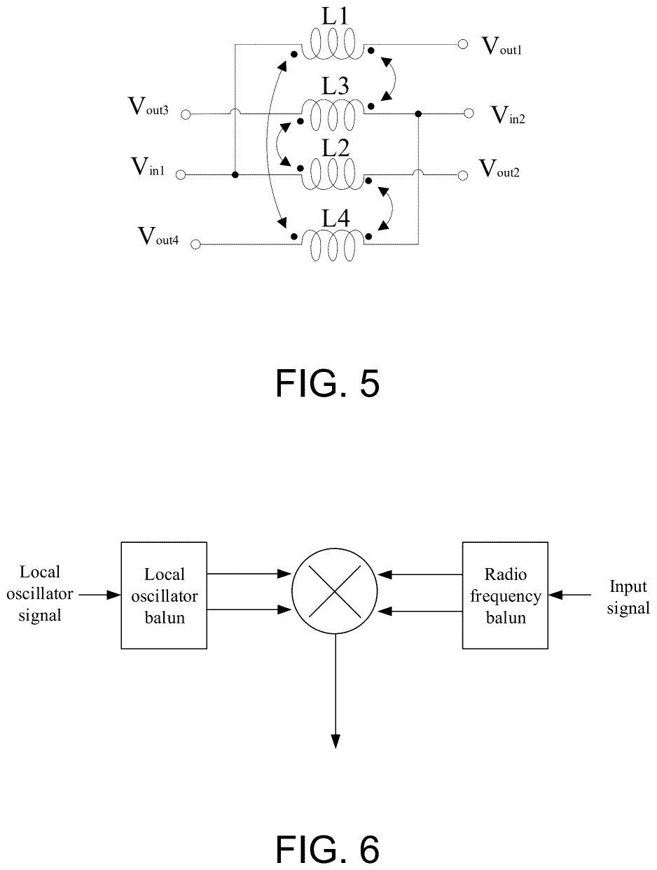

FIG. 5 illustrates a schematic diagram of the coupling relation of the balun illustrated in FIG. 2 in another embodiment. As illustrated in FIG. 5, a cross-coupled structure is adopted in the balun. The cross-coupled structure refers that an arbitrary one of the inductors in one coils is coupled to the two inductors in the other coil, respectively. As illustrated in FIG. 5, the inductor L1 and the inductor L3 form one set of coupling relation, the inductor L1 and the inductor L4 form one set of coupling relation, the inductor L2 and the inductor L3 form one set of coupling relation, and the inductor L2 and inductor L4 form one set of coupling relation. In the balun structure illustrated in FIG. 5, the inductors L1, L2, L3 and L4 are respectively one set of coil, and the four sets of coils are cross-enwound and wired.

Preferably, the coils in FIGS. 4 and 5 are microstrip lines.

A mixer is further provided according to another aspect of the present disclosure.

FIG. 6 illustrates a schematic block diagram of a structure of the mixer in the present disclosure. As illustrated in FIG. 6, the mixer includes a local oscillator balun, a radio frequency balun and a frequency mixing core.

The input terminal of the local oscillator balun is in connection with the local oscillator to receive the local oscillator signal, that is, the input terminal of the local oscillator balun is configured to input the local oscillator signal, and the local oscillator balun is configured to convert the single-ended local oscillator signal into a differential local oscillator signal. The differential output terminal of the local oscillator balun is in connection with the local oscillator input terminal of the frequency mixing core, so as to input the differential local oscillator signal to the frequency mixing core.

The input terminal of the radio frequency balun is configured to connect the input signal. The radio frequency balun is configured to convert the single-ended input signal into a differential input signal. The differential output terminal of the radio frequency balun is in connection with the radio frequency input terminal of the frequency mixing core, so as to input the differential input signal to the frequency mixing core.

The frequency mixing core is configured to mix the differential input signal with the differential local oscillator signal, so as to perform the frequency migration on the input signal to generate a corresponding frequency conversion signal. When the frequency of the frequency conversion signal is more than that of the input signal, the mixer implements an up-conversion, and when the frequency of the frequency conversion signal is less than that of the input signal, the mixer implements a down-conversion.

In particular, the balun according to an arbitrary one of the above-mentioned embodiments in the present disclosure is adopted by the local oscillator balun or the radio frequency balun. That is, in the specific embodiments, the balun according to an arbitrary one of the above-mentioned embodiments in the present disclosure is adopted by the local oscillator balun, and the other existing or future baluns are adopted by the radio frequency balun, or the balun in an arbitrary one of the above-mentioned embodiments in the present disclosure is adopted by the radio frequency balun, the other existing or future baluns are adopted by the local oscillator balun, or the balun in an arbitrary one of the above-mentioned embodiments in the present disclosure is adopted by the local oscillator balun and the radio frequency balun.

Preferably, the local oscillator balun in the mixer can be set as the balun described in the present disclosure.

The existing or future passive frequency conversion circuit that can implement the frequency migration is adopted by the frequency mixing core.

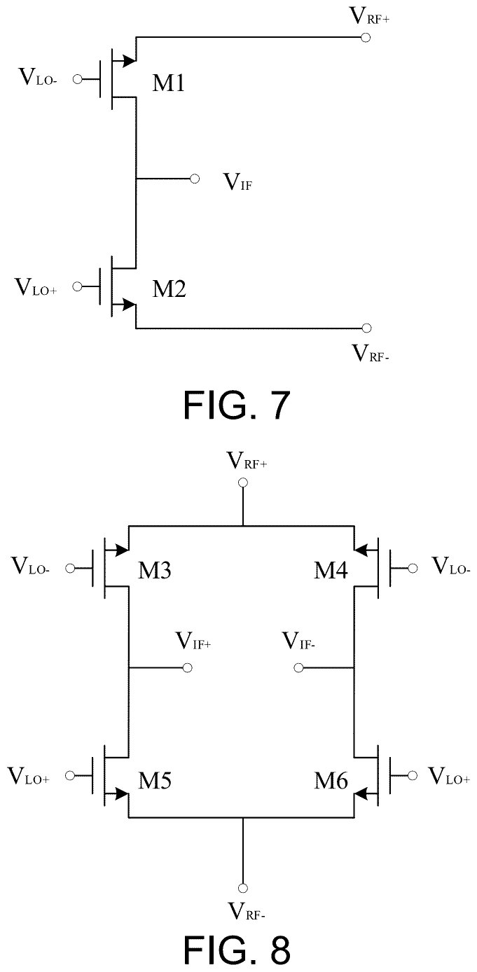

FIG. 7 illustrates a single-ended passive frequency mixing core circuit in one embodiment. As illustrated in FIG. 7, in this embodiment, the frequency mixing core includes a switch transistor M1 and a switch transistor M2. The gate of the switch transistor M1 and the gate of switch transistor M2 form the local oscillator input terminal V_{LO-} and the local oscillator input terminal V_{LO+} of the frequency mixing core, which are configured to connect to the differential output terminals of the local oscillator balun. The source of switch transistor M1 and the source of switch transistor M2 form the radio frequency input terminal V_{RF}+ and the radio frequency input terminal V_{RF}− of the frequency mixing core, which are configured to connect to the differential output terminals of the radio frequency balun. The drain of switch transistor M1 is in connection with the drain of switch transistor M2 to form the output terminal V_{IF} of the frequency mixing core, the output terminal V_{IF} is a single-ended output terminal that is configured to output the single-ended frequency conversion signal.

FIG. 8 illustrates a circuit of a double-balanced passive frequency mixing core in one embodiment. As illustrated in FIG. 8, in this embodiment, the frequency mixing core includes the switch transistor M3 and the switch transistor M4 that are symmetrically arranged with each other, and the switch transistor M5 and the switch transistor M6 that are symmetrically arranged with each other. The source of the switch transistor M3 is in connection with the source of the switch transistor M4 to form the positive input terminal V_{RE}+. The source of the switch transistor MS is in connection with the source of the switch transistor M6 to form the negative input terminal V_{RF}−, and the positive input terminal V_{RF}+ and the negative input terminal V_{RF}− constitute the radio frequency input terminals, which are configured to connect to the differential output terminals of the radio frequency balun. The gate of the switch transistor M3 and the gate of the switch transistor M5 form one set of local oscillator input terminals V_{LO} and V_{LO+} of the frequency mixing core, which is configured to connect to the differential output terminals of the local oscillator balun. The gate of the switch transistor M4 and the gate of the switch transistor M6 form the other set of local oscillator input terminals V_{LO-} and V_{LO+} of the frequency mixing core, which is configured to connect to the differential output terminals of the local oscillator balun. The drain of the switch transistor M3 is in connection with the drain of the switch transistor M5 to form the positive output terminal V_{IF+} of the frequency mixing core, and the drain of the switch transistor M4 is in connection with the drain of the switch transistor M6 to form the negative output terminal V_{IF-} of the frequency mixing core. The positive output terminal V_{IF+} and the negative output terminal V_{IF-} form the mixing and differential output terminals, which is configured to output the differential frequency conversion signals.

The switch transistors in the above-mentioned embodiments refer to a tri-port transistor without amplification function, such as a MOS transistor.

FIG. 9 illustrates a schematic diagram of a circuit structure of a diode frequency mixing core in one embodiment. As illustrated in FIG. 9, the frequency mixing core is formed by four frequency mixing branches MR1, MR2, MR3 and MR4 that are connected with each other from a starting end to a rear end. Each of the frequency mixing branches includes a plurality of diodes from D1 to DN in series, and N is a natural number more than or equal to 2.

The plurality of diodes in series are adopted as the frequency mixing branch, which can reduce the voltage swing that a single diode requires to bear when the high power is inputted, thereby increasing the IdB compression point of the passive mixer and improving the linearity of the passive mixer.

Diodes in series refers that the anode of the previous diode is in connection with the cathode of the subsequent diode. In a frequency mixing branch which is formed by N diodes in series, the anode of an arbitrary diode Dᵢ is in connection with the cathode of diode Dᵢ₊₁, where N−1≥i≥1, and the cathode of diode D₁ forms the cathode of the frequency mixing branch, and the anode of diode DN forms the anode of the frequency mixing branch.

The frequency mixing branches connected from a starting end to a rear end refer that the anode of the previous frequency mixing branch is in connection with the cathode of the subsequent frequency mixing branch. As illustrated in FIG. 2, in the frequency mixing core R1, the anode of the frequency mixing branch MR1 is in connection with the cathode of the frequency mixing branch MR2 to form the first mixing point T1, the anode of the frequency mixing branch MR2 is in connection with the cathode of the frequency mixing branch MR3 to form the second mixing point T2, the anode of the frequency mixing branch MR3 is in connection with the cathode of the frequency mixing branch MR4 to form the third mixing point T3, and the anode of the frequency mixing branch MR4 is in connection with the cathode of the frequency mixing branch MR1 to form the fourth mixing point T4. The first frequency mixing point T1 and the third frequency mixing point T3 form the local oscillator input terminals V_{LO+} and V_{LO-}, and the second frequency mixing point T2 and the fourth frequency mixing point T4 form the radio frequency input terminals V_{RF}+ and V_{RF}−.

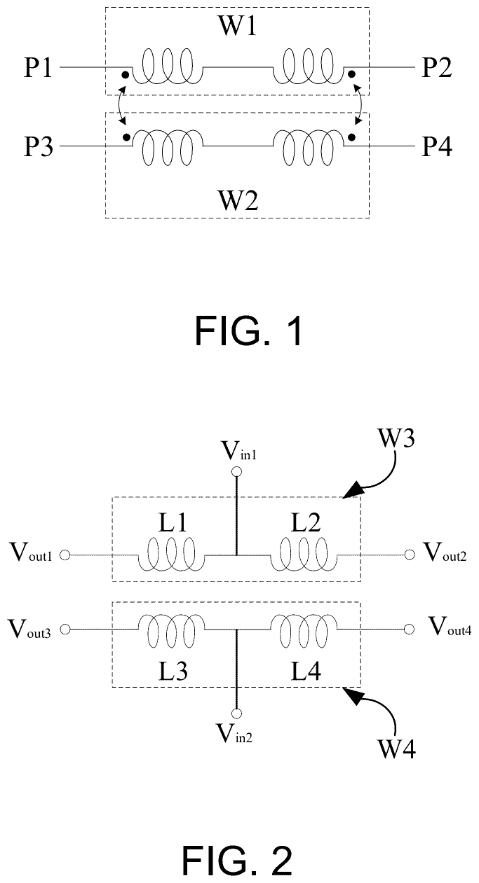

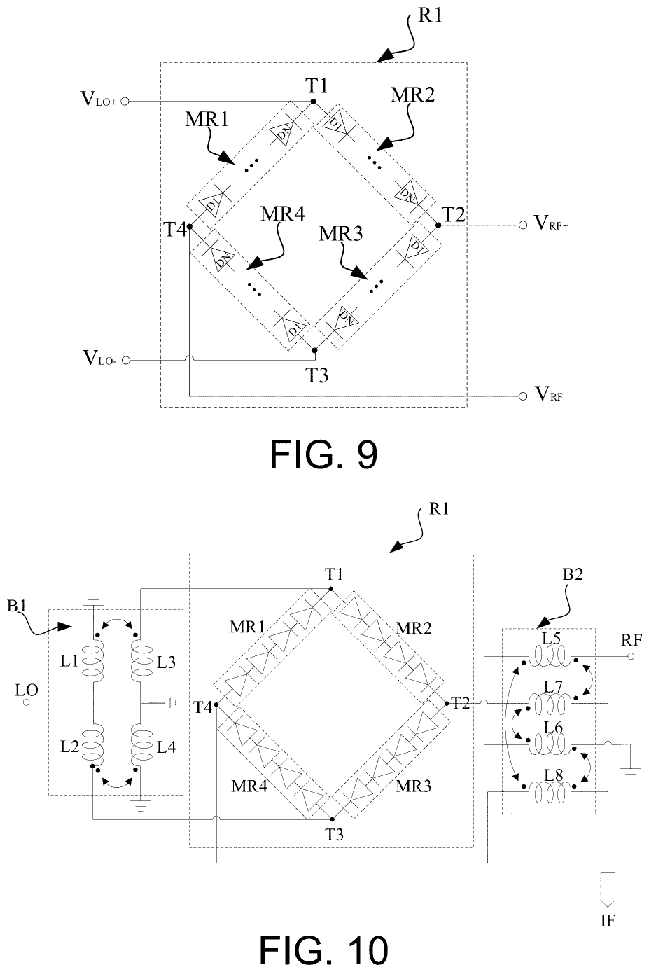

FIG. 10 illustrates a schematic diagram of a circuit structure of a mixer in one embodiment. As illustrated in FIG. 10, the balun circuit illustrated in FIG. 2 is adopted by the local oscillator balun B1 of the mixer in this embodiment, and a transformer balun is adopted by the radio frequency balun B2, such as the balun structure as illustrated in FIG. 1.

One set of differential output terminals (Vₒᵤₜ₂ and Vₒᵤₜ₃ in FIG. 2) of the local oscillator balun B1 are grounded, respectively, and the other set of differential output terminals (Vₒᵤₜ₁ and Vₒᵤₜ₄ in FIG. 2) are served as the differential output terminals of the local oscillator signal, which are in connection with the first frequency mixing point T1 and the third frequency mixing point T3 of the frequency mixing core R1, respectively. One of the input terminals of the local oscillator balun (Vᵢₙ₁ in FIG. 2) is in connection with the local oscillator input signal LO, and the other input terminal of the local oscillator balun (Vᵢₙ₂) in FIG. 2) is grounded.

One terminal (P1 in FIG. 1) of the two terminals of one coil (coil W1 in FIG. 1) of the radio frequency balun B2 is in connection with the radio frequency input signal RF, and the other end (P2 in FIG. 1) is grounded. Two terminals of the other coil (coil W2 in FIG. 1) of the radio frequency balun B2 are in connection with the second frequency mixing pint T2 and the fourth frequency mixing pint T4 of the frequency mixing core R1, respectively.

Preferably, a cross-coupled structure is adopted by the radio frequency balun. The cross-coupled structure refers that the two inductors of one of the coils in the balun are coupled to the two inductors in the other coil, respectively, thereby implementing the structure that four inductors generate four coupling relations. As illustrated in FIG. 10, one coil of the radio frequency balun B2 includes the inductor L5 and the inductor L6 in series, and the other coil of the radio frequency balun B2 includes the inductor L7 and the inductor L8, the inductor L5 is coupled to the inductor L7 and the inductor L8, respectively, and the inductor L6 is coupled to the inductor L7 and the inductor L8, respectively.

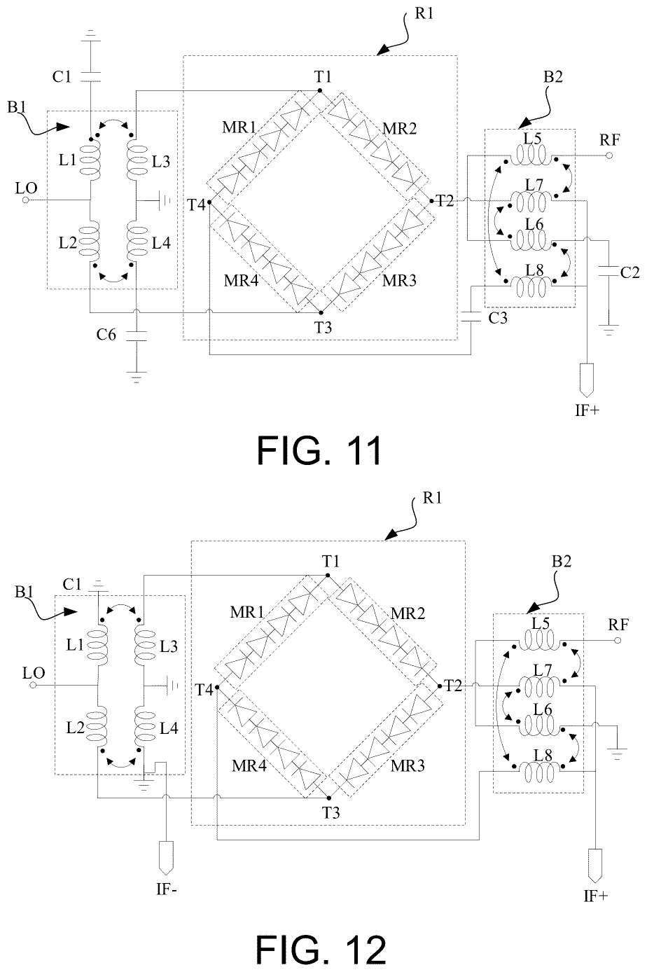

FIG. 11 illustrates a schematic diagram of a circuit structure of a mixer in another embodiment. The differences between the embodiment illustrated in FIG. 11 and the mixer illustrated in FIG. 10 lie in that the differential output terminals (Vₒᵤₜ₂ and Vₒᵤₜ₃ in FIG. 2) configured to ground in the local oscillator balun B1 are grounded through the capacitor C1 and the capacitor C6, respectively, and the inductor L6 of the radio frequency balun B2 is grounded through the capacitor C2.

The Capacitors C1, C6 and C2 are capable of adjusting the isolation between the input terminal and the output terminal of the balun, thereby implementing the adjustment of matching impedance and the balance. In some other embodiments, the capacitors C1, C6, and C2 can be replaced by the inductors. It is required to emphasize that when in the balun as illustrated in FIG. 2 is adopted, in the case where the capacitor illustrated in FIG. 11 is set, the completely symmetrical structure and parameters are required to be adopted to ensure that the circuit structure and the parameters for each set of the differential output terminals of the balun B1 are completely consistent, thus ensuring that the balun characteristics of the structure are completely consistent.

Further, the radio frequency balun B2 is in connection with the fourth frequency mixing point T4 through the capacitor C3, which can implement the adjustment of the peak frequency of the third-order intermodulation signal of the mixer, and can further improve the matching and the impedance matching degree and the balance.

FIG. 12 illustrates a schematic diagram of a circuit structure of a mixer in another embodiment. As illustrated in FIG. 12, an intermediate frequency output terminal IF− is drawn from the grounded side of the inductor L4 of the local oscillator balun B1, and the intermediate frequency output terminal IF+ is drawn from the connection point of the inductor L7 and the inductor L8 of the balun B2, and the intermediate frequency output terminal IF− and the intermediate frequency output terminal IF− form one set of the differential output terminals. The differences between the embodiment illustrated in FIG. 12 and the embodiment illustrated in FIG. 10 lie in that the intermediate frequency output terminal IF' drawn from the connection point of the inductor L7 and the inductor L8 of the balun B2 in FIG. 10 is varied to a differential output terminal from a single-ended output terminal.

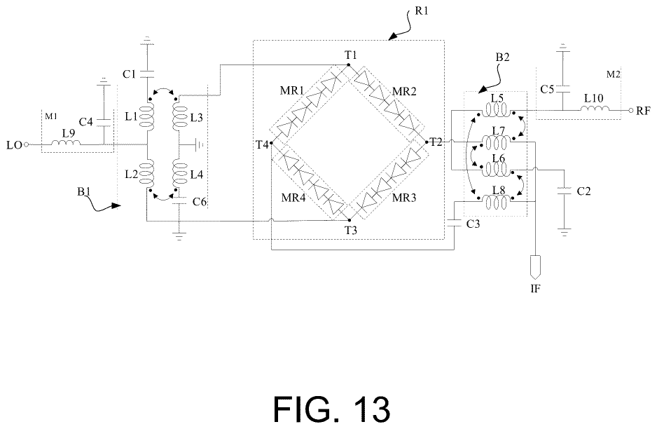

In specific embodiments, the mixer further includes other adapted functional units. FIG. 13 illustrates a schematic diagram of a circuit structure of a mixer in another embodiment. The embodiment illustrated in FIG. 13 further includes a matching circuit M1 and a matching circuit M2 based on the embodiment illustrated in FIG. 11.

The matching circuit M1 is set at the input terminal of the local oscillator balun B1 to implement the impedance matching at the local oscillator terminal. The matching circuit M2 is set at the input terminal of the radio frequency balun B2 to implement the impedance matching at the input terminal.

In the embodiment illustrated in FIG. 13, the matching circuit M1 includes an inductor L9 and a capacitor C4, the matching circuit M2 includes an inductor L10 and a capacitor C5. In other embodiments, those skilled in the art can design the adopted impedance matching circuit according to the impedance matching requirements.

Although embodiments illustrated in the above-mentioned FIGS. 10 to 13 are all illustrated with the balun structure illustrated in FIG. 1, and with the connection method illustrated in FIG. 3 as the connection method of the local oscillator balun B1, it is understood by those skilled in the art that the structure or the coupling method of the balun adopted in an arbitrary balun in the above-mentioned embodiments can be adaptively applied to the embodiments in FIGS. 10 to 13, and can be served as the local oscillator balun or the radio frequency balun.

The connection method for each port are exemplarily illustrated by the above-mentioned embodiments. It is understood by those skilled in the art that the connection method for the multiple equivalent ports arranged symmetrically and with the same structure can be exchanged according to an example in an arbitrary one of the above-mentioned embodiments, and the final functions implemented by the multiple equivalent ports do not affect.

The previous descriptions are provided for those skilled in the art to implement the various aspects described in the present disclosure. However, it should be understood that the protection scope of the present disclosure should be governed by the attached claims and should not be limited to the specific structures and components of the embodiments explained above. Within the spirit and scope of the present disclosure, various changes and modifications to the embodiments can be made by those skilled in the art, and these changes and modifications also fall within the protection scope of the present disclosure.

1. A balun comprising a fist coil and a second coil coupled to each other, wherein an intermediate point of the first coil forms a first input terminal of the balun, an intermediate point of the second coil forms a second input terminal of the balun, both terminals of the first coil forms a first output terminal and a second output terminal of the balun, respectively, both terminals of the second coil form a third output terminal and a fourth output terminal of the balun, respectively, the third output terminal and the fourth output terminal are coupling terminals of the first output terminal and the second output terminal, respectively, and the first output terminal and the fourth output terminal form a first set of differential output terminals, and the second output terminal and the third output terminal form a second set of differential output terminals.

2. The balun according to claim 1, wherein one of the first input terminal and the second input terminal is configured to connect an input signal, another one of the first input terminal and the second input terminal is grounded, the first set of differential output terminals is configured to output a differential signal, and the second set of differential output terminals is grounded.

3. The balun according to claim 1, wherein the first coil is divided into a first inductor and a second inductor that are in equal to each other by the intermediate point of the first coil, the second coil is divided into a third inductor and a fourth inductor that are in equal to each other by the intermediate point of the second coil, the first inductor is coupled to the third inductor, and the second inductor is coupled to the fourth inductor.

4. The balun according to claim 1, wherein the first coil is divided into a first inductor and a second inductor that are in equal to each other by the intermediate point of the first coil, the second coil is divided into a third inductor and a fourth inductor that are in equal to each other by the intermediate point of the second coil, wherein the first inductor is coupled to the third inductor and the fourth inductor, respectively, and the second inductor is coupled to the third inductor and the fourth inductor, respectively, to form a cross-coupled structure.

5. A mixer, comprising a local oscillator balun, a frequency mixing core and a radio frequency balun, wherein an input terminal of the local oscillator balun is in connection with a local oscillator signal, a differential output terminal of the local oscillator balun is in connection with a local oscillator input terminal of the frequency mixing core, an input terminal of the radio frequency balun is in connection with an input signal, and a differential output terminal of the radio frequency balun is in connection with a radio frequency input terminal of the frequency mixing core, wherein the balun according to claim 1 is adopted by the local oscillator balun and/or the radio frequency balun.

6. The mixer according to claim 5, wherein the frequency mixing core includes four frequency mixing branches connected from a starting terminal to a rear terminal, each frequency mixing branch includes a plurality of diodes in series, the four frequency mixing branches are sequentially connected with each other from a starting terminal to a rear terminal, connection points of the four frequency mixing branches form a first frequency mixing point, a second frequency mixing point, a third frequency mixing point and a fourth frequency mixing point, respectively, the first frequency mixing point and the third frequency mixing point form a local oscillation signal input terminal of the frequency mixing core, and the second frequency mixing point and the fourth frequency mixing point form an input signal terminal of the frequency mixing core.

7. The mixer according to claim 6, wherein each of the frequency mixing branches includes four diodes in series.

8. The mixer according to claim 6, wherein the balun is adopted by the local oscillator balun.

9. The mixer according to claim 5, wherein the mixer is a single-ended mixer, the frequency mixing core includes a first switch transistor and a second switch transistor, a gate of the first switch transistor and a gate of the second switch transistor form the local oscillator input terminal, a source of the first switch transistor and a source of the second switch transistor form the radio frequency input terminal, and a drain of the first switching transistor is in connection with a drain of the second switch transistor to form a mixing output terminal of the mixer.

10. The mixer according to claim 5, wherein the mixer is a dual-balanced mixer, the frequency mixer core includes a third switch transistor and a fourth switch transistor symmetrically arranged with each other, as well as a fifth switch transistor and a sixth switch transistor symmetrically arranged with each other, a gate of the third switch transistor and a gate of the fifth switch transistor form one set of local oscillator input terminals, a gate of the fourth switch transistor and a gate of the sixth switch transistor form another set of local oscillator input terminals, a source of the third switch transistor is in connection with a source of the fourth switch to form a positive input terminal, a source of the fifth switch transistor is in connection with a source of the sixth switch transistor to form a negative input terminal, the positive input terminal and the negative input terminal form the radio frequency input terminal, a drain of the third switch transistor is in connection with a drain of the fourth switch transistor to form a positive output terminal of the mixer, a drain of the fifth switch transistor is in connection with a drain of the sixth switch transistor to form a negative output terminal of the mixer, and the positive output terminal and the positive output terminal form a differential output terminal of the mixer.
